(19) United States
(12) Patent Application Publication
(10) Pub. No.: US 2005/0285130 A1
(43) Pub. Date: Dec. 29, 2005

(54) LIGHT EMITTING DIODE HAVING AN ADHESIVE LAYER AND MANUFACTURING METHOD THEREOF

(76) Inventor: Min-Hsun Hsieh, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/160,353

(22) Filed: Jun. 21, 2005

(30) Foreign Application Priority Data
Jun. 24, 2004 (TW) 093118484

(51) Int. Cl. H01L 33/00; H01L 21/00

(52) U.S. Cl. 257/98; 257/103; 438/46

(57) ABSTRACT

A light emitting diode having an adhesive layer and manufacturing method thereof is disclosed. An adhesive layer having a thickness of about 0.1 μm to 1 μm is used to adhere an LED stack and a high heat-dissipating substrate, wherein the substrate is of a thermal conductivity greater than or equal to 100 W/mk. The present invention enhances the heat-dissipating effect of the light emitting diode so as to improve the stability and the light-emitting efficiency of the light emitting diode.

### BACKGROUND OF THE INVENTION

1. Field of the Invention

This invention relates to a light emitting diode having an adhesive layer and manufacturing method thereof, and more particularly, to a high heat-dissipating light emitting diode and manufacturing method thereof.

2. Description of the Related Art

Light emitting diodes (LED) have been widely utilized. For example, LEDs are utilized in optical display devices, traffic signs, data storing devices, communication devices, lighting devices, and medical equipment. Increasing the luminance of LEDs has therefore become an important task in the field.

Disclosed in U.S. Pat. No. 10/142,954 are an LED and manufacturing method thereof, wherein An LED epitaxial structure is formed on a first light absorbing substrate, and then a dielectric adhesive layer of polymer material is utilized to connect the LED epitaxial structure to a second high thermal conductivity substrate so as to enhance the heat dissipation of the chip and the light-emitting efficiency of the LED. As disclosed in the above-mentioned patent, the epitaxial stack is grown on the first light-absorbing substrate and then the adhesive layer is utilized to adhere the epitaxial stack and the second substrate. Next, the first light-absorbing substrate is removed to reduce the thermal resistance, to improve the heat dissipation and to enhance the light-emitting efficiency. The thermal resistance of an LED device is corresponding to its thickness and thermal conductivity of compositions thereof. The relationship between them is shown in the following equation:
Thermal resistance Rₜₕ=L/kA equation (1)

In the above-mentioned patent, the thermal resistance of the whole LED structure is equal to the thermal resistance of the sum of the LED epitaxial structure, the dielectric adhesive layer, and the substrate. Here, the thermal resistance is calculated as shown in the following equation:
Device thermal resistance=LED epitaxial structure thermal resistance+dielectric adhesive layer thermal resistance+substrate thermal resistance
(L/kA)_{device}=(L/kA)_{LED epitaxial structure}+(L/kA)_{dielectric adhesive layer}+(L/kA)_{second substrate} equation (2)

Furthermore, the thermal resistance of the LED device originally formed on the first substrate is equal to the sum of the epitaxial structure thermal resistance and the substrate thermal resistance. The relationship among them can be described by the following equation:
Original device thermal resistance=epitaxial structure thermal resistance+first substrate thermal resistance
(L/kA)_{original device}=(L/kA)_{LED epitaxial structure}(L/kA)_{first substrate} equation (3)

As shown in equation (2) and equation (3), even though the high heat-dissipating substrate is utilized, when the sum of the adhesive layer thermal resistance and the high heat-dissipating substrate thermal resistance is larger than the original first substrate thermal resistance, the heat dissipation characteristic of the high thermal conductivity substrate of the LED device is not good enough and consequently the LED device has the disadvantage of poor heat-dissipation.

### SUMMARY OF THE INVENTION

To avoid the above-mentioned disadvantage,an object of the invention is to provide a high heat-dissipating light emitting diode and manufacturing method thereof.

One aspect of the present invention is to utilize the heat-dissipating characteristic of the substrate having a high thermal conductivity. Another object of the present invention is to utilize a preferable thickness of the adhesive layer and the second substrate of high thermal conductivity so as to reduce the thermal resistance of the device and improve the heat-dissipating efficiency.

A traditional LED structure of the prior art comprises a first substrate on which is formed an epitaxial stack, which can be made of the material selected from the group consisting of GaAs and Ge. Assuming that the device area is A, the thermal conductivity of the first substrate is k1 (W/mk), the thickness of the first substrate is x1 μm, the thermal conductivity of the epitaxial stack is k2 (W/mk), and the thickness of the epitaxial stack is x2 μm, then the thermal resistance of the device of the first substrate is calculated by the following equation:
Rth1_{original device}=(x2/k2*A)_{epitaxial stack}+(x1/k1*A)_{first substrate}

A dielectric adhesive layer of polymer materials is utilized to connect the LED epitaxial stack to the second substrate having high conductivity so as to replace the LED structure of the first substrate. This structure comprises a second substrate having a high thermal conductivity, an epitaxial stack, and a dielectric adhesive layer of polymer materials for connecting the epitaxial stack to the second substrate. Assuming that the device area is A, the thermal resistance factor of the epitaxial stack is k2 (W/mk), the thickness of the epitaxial stack is x2 μm, the thermal conductivity of the adhesive layer is k3 (W/mk), the thickness of the adhesive layer is x3 μm, the thermal conductivity of the second substrate is k4 (W/mk), and the thickness of the second substrate is x4 μm, then the thermal resistance of the device is calculated by the following equation:
Rth2_{device}=(x2/k2*A)_{epitaxial stack}+(x3/k3*A)_{adhesive layer}+(x4/k4*A)_{second substrate}

As mentioned above, utilizing the adhesive layer for connecting the epitaxial stack to the second substrate of high thermal conductivity to replace the first substrate reduces the thermal resistance and increases the heat-dissipating efficiency. It follows that Rth2 should be smaller than Rth1.

According to an embodiment of the present invention, an LED structure comprises a second substrate having high thermal conductivity for replacing a first substrate, an epitaxial stack, and a BCB adhesive layer for connecting the epitaxial stack. Assume that the device area is A, the thermal conductivity of the epitaxial stack is 6 (W/mk), the thickness of the epitaxial stack is 3 μm, the thermal conductivity of the BCB adhesive layer is 0.2 (W/mk), the thickness of the adhesive layer is x2 μm, the thermal conductivity of the second substrate is k3 (W/mk), and the thickness of the second substrate is 170 μm. The first substrate is composed of GaAs, whose thermal conductivity is 50 (W/mk). Please note that thermal conductivities of normal materials and organic materials of LEDs can be seen in table 1 and table 2:

TABLE 1
a table of the thermal conductivities of normal materials of LEDs

| Material | Thermal conductivity (W/mk) |
|---|---|
| GaAs | 44-58 |
| Al_{0.5}Ga_{0.5}As | 11 |
| (Al_{0.5}Ga_{0.5})In_{0.5}P | 6 |
| Ga_{0.5}In_{0.5}P | 5 |
| GaP | 75-100 |
| Sapphire | 35-40 |
| GaN | a.130 b.170 |
| Si | 125-150 |
| SiC | 270 |
| Copper | 393 |
| Silver | 418 |
| Gold | 297 |
| Aluminum | 240 |
| Au-Sn(80-20) | 57 |
| In | 81.8-86 |
| Aluminum Nitride | a.170-200 b.285 |
| SiO₂ | 1.5 |
| Glass | 0.8 |
| Al₂O₃ | 10-35 |

References:

(1) R. R. Tummala and E. J. Rymaszewski: “Microelectronics Packaging Handbook” (van Nostrand Reinhold, 1988)

(2) G. Slack, J. Phys. Chem. Solids 34,321(1973)

(3) P. D. Maycock, Thermal Conductivity of Silicon, Germanium, III-V Compounds and III-V Alloys, Solid-State Electronics, vol. 10. pp 161-168, 1967s

(4) http://hyperphysics.phy-astr.gsu.edu/hbase/mecref.html#c1

TABLE 2
a table of the thermal conductivities of organic materials of LEDs

| Material | Thermal conductivity (W/mk) |
|---|---|
| Epoxy-Kevlar(x-y) (60%) | 0.2 |
| Polymide-Quartz(z-axis) | 0.35 |
| Polymide | 0.2 |
| Fr-4(x-y plane) | 0.2 |
| Benzocyclobutene | 0.2 |
| Teflon( ™DuPont Co.) | 0.1 |

References:

(1) R. R. Tummala and E. J. Rymaszewski: “Microelectronics Packaging Handbook” (van Nostrand Reinhold, 1988)

Utilizing the second substrate of high thermal conductivity to replace the first substrate can increase the heat-dissipating efficiency only if the above-mentioned Rth2 is less than the original thermal resistance Rth1 of the GaAs first substrate. In view of this statement, the relationship between the Rth1 and Rth2 can be determined by the following equations:
Rth1_{original device}=(3/6*A)_{epitaxial stack}+(170/50*A)_{first substrate}
Rth2_{device}=(3/6*A)_{epitaxial stack}+(x3/0.2*A)_{adhesive layer}+(170/k4*A)_{second substrate}
Rth2_{device}−Rth1_{original device}<0

Therefore, we can obtain the following relationship:
x3/0.2+170/k4<3.4

Table 3 shows the optimum thickness of the adhesive layer of different types of substrates having high thermal conductivity to replace the GaAs substrate, wherein the adhesive layer is made of BCB.

TABLE 3

| | Thermal | |
|---|---|---|
| | conductivity (k4) of | Thickness (x3) of |
| Material of the | the second | BCB adhesive layer |
| second substrate | substrate (W/mk) | (μm) |
| Sapphire | 35 | <0 |
| GaP | 100 | <0.34 |
| GaN | 130 | <0.418 |
| Si | 150 | <0.453 |
| Aluminum (Al) | 240 | <0.538 |
| SiC | 270 | <0.554 |
| Gold | 297 | <0.556 |
| Copper (Cu) | 393 | <0.593 |
| Silver(Ag) | 418 | <0.599 |

An LED structure utilizing an adhesive layer to connect an LED epitaxial stack to a second substrate in order to replace the first substrate is disclosed. The relationship between the thermal conductivity of the second substrate and the thickness of the adhesive layer is shown in FIG. 1. As shown in FIG. 1, the condition of increasing the heat-dissipating efficiency is that the thickness of the adhesive layer has to be less than 0.5 μm. But because the surface of the epitaxial stack is not so flat, the epitaxial stack has thickness differences in itself. Referring to FIGS. 2, 3, in the real implementation, the BCB adhesive layer is utilized to connect the epitaxial stack to the Si substrate of high thermal conductivity in order to replace the original GaAs substrate. Furthermore, if the thickness of the adhesive layer is less than or equal to 1 μm, the LED structure can have better heat-dissipating efficiency and light-emitting efficiency than that of the prior art LED structure having a GaAs substrate. But if the thickness of the adhesive layer is less than 0.1 μm, the connection yield is very low. Therefore, the optimum thickness of the adhesive layer is between 0.1 μm and 1 μm. Furthermore, a reaction layer can be formed between the adhesive layer and the second substrate or between the adhesive layer and the epitaxial stack to increase the adhesive force so that the connection yield can be raised.

The above-mentioned LED structure is produced through the following steps. First, the adhesive layer is utilized to connect the LED epitaxial stack to the second substrate of high thermal conductivity. Secondly, the connected LED epitaxial stack, the adhesive layer, and the second substrate are placed between two graphite plates. Thirdly, the two graphite plates are heated and pressured to increase the adhesive force. The graphite characteristics of good heat radiation and soft quality can be well utilized to form an adhesive layer having an even thickness.

The inventor of the present invention obtains the same result in an experiment. According to the experimental data, in this experiment, the thermal conductivity of the second substrate is larger than 100 W/mk, the thickness BCB adhesive layer is less than or equal to 1 μm, and indeed the heat-dissipating efficiency is better than the prior art GaAs substrate. Furthermore, in this experiment, the thickness of BCB is between 0.5 μm and 0.8 μm. The experiment result is shown in Table 4. In another experiment, the same Si substrate is utilized, but a BCB adhesive layer having different thickness is formed. The experiment result is shown in Table 5.

TABLE 4

| | Thermal | |
|---|---|---|
| | conductivity of the | 12 mil LED |
| | second substrate | saturation current |
| LED structure | (μm) | (mA) |
| EPI/GaAs | 44-58 | 160-180 |
| EPI/BCB/Si | 125-150 | 180-200 |
| EPI/BCB/SiC | 270 | 180/220 |
| EPI/BCB/Sapphire | 35-40 | 100-120 |
| EPI/BCB/Glass | 0.8 | 50-60 |

TABLE 5

| | Thickness of the | 12 mil LED |
|---|---|---|
| | BCB adhesive | saturation |
| LED structure | layer (W/mk) | current (mA) |
| EPI/BCB/Si | 10 | 60 ˜ 80 |
| | 5 | About 120 |
| | 3 | About 140 |
| | 1 | About 200 |
| | 0.5 | 200 ˜ 210 |

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a relationship between thermal conductivity of a substrate and thickness of an adhesive layer.

FIG. 2 and FIG. 3 are three-dimensional diagrams illustrating a flat degree of an epitaxial stack surface.

FIG. 4 is a diagram of a preferred embodiment of an LED structure according to the present invention.

FIG. 5 is a diagram of a first layer structure before connection when producing the LED structure shown in FIG. 4.

FIG. 6 is a diagram illustrating production of the adhesive layer having 0.1 μm-1 μm thickness when producing the LED structure shown in FIG. 4.

FIG. 7 is a diagram of a second layer structure after connecting the first layer to the second substrate but before removing the first substrate.

FIG. 8 is a diagram of a third layer structure after removing the first substrate when producing the LED structure shown in FIG. 4.

FIG. 9 is a diagram of another embodiment of an LED structure according to the present invention.

FIG. 10 is a diagram of a fourth layer structure before connection when producing the LED structure shown in FIG. 9.

FIG. 11 is a diagram of a fifth layer structure before connection when producing the LED structure shown in FIG. 9.

FIG. 12 is a diagram of a sixth layer structure after connecting the fourth layer and the fifth layer but before removing the first substrate when producing the LED structure shown in FIG. 9.

FIG. 13 is a diagram of a seventh layer structure after removing the first substrate when producing the LED structure shown in FIG. 9.

FIG. 14 is a diagram of the other embodiment of an LED structure according to the present invention.

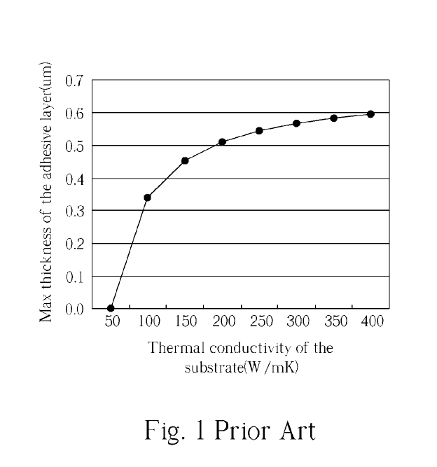

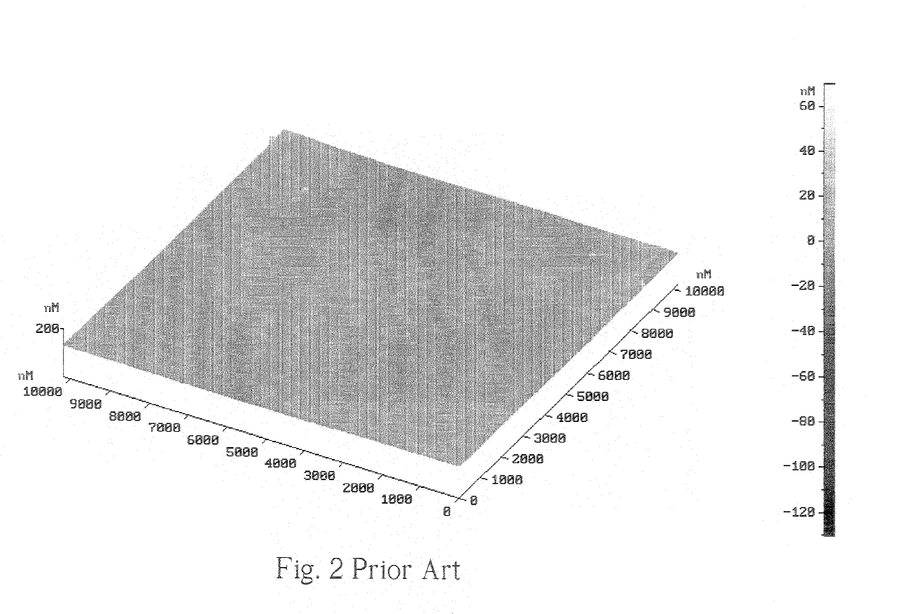

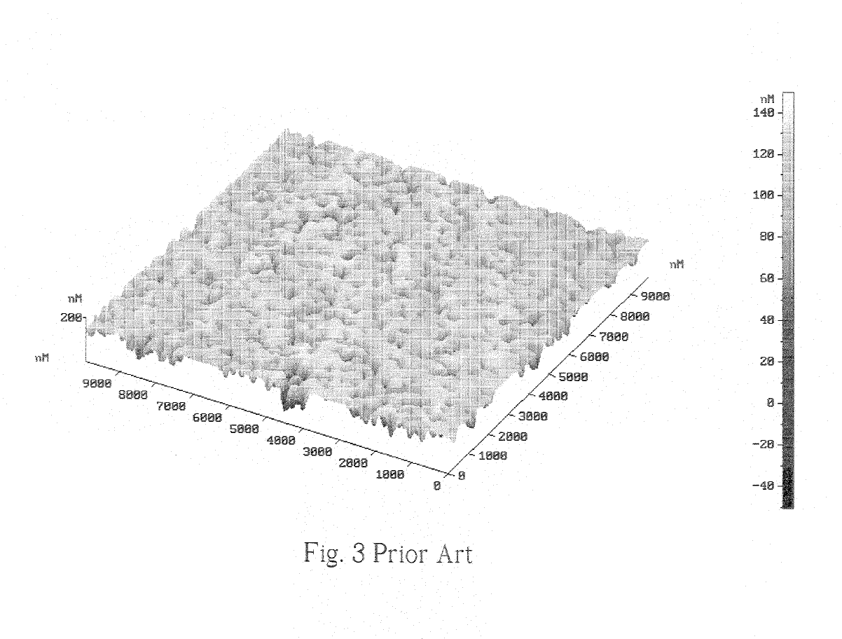

### DETAILED DESCRIPTION

### Embodiment 1

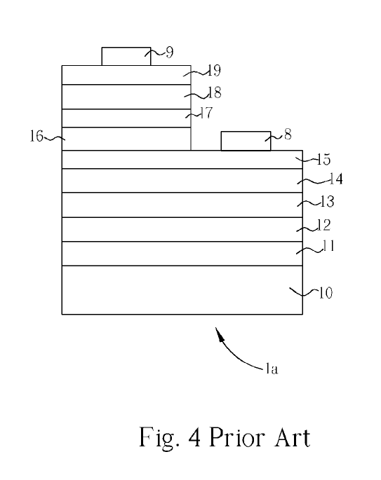

Referring to FIG. 4, the LED 1a comprises a second substrate 10 having high thermal conductivity, an adhesive layer 11 having a 0.1 μm-1 μm thickness formed on the second substrate 10, a first protection layer 12 formed on the adhesive layer 11, a reflection layer 13 formed on the first protection layer 12, a second protection layer 14 formed on the reflection layer 13, a first contact layer 15 formed on the second protection layer 14, wherein the upper surface of the first contact layer 15 comprises a first surface area and a second surface area. The LED 1 a further comprises a first cladding layer 16 formed on the first surface area, a light-emitting layer 17 formed on the first cladding layer 16,a second cladding layer 18 formed on the light-emitting layer 17, a second contact layer 19 formed on the second cladding layer 19, a first wiring electrode 9 formed on the second cladding layer 19, and a second wiring electrode 9 formed on the second surface area.

Referring to FIGS. 4, 5, and 6, the LED 1 a is produced by the following steps:

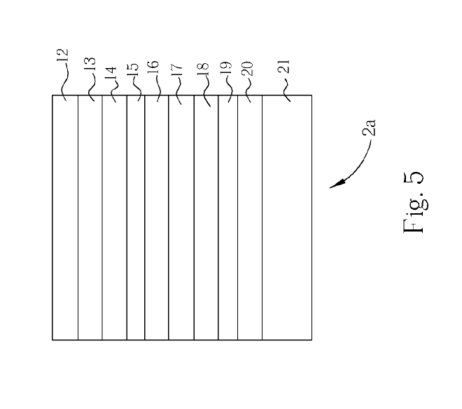

Step 100: Sequentially form an etching termination layer 20, a second contacting layer 19, a second cladding layer 18, a light-emitting layer 17, a first cladding layer 16, a first contact layer 15, a second protection layer 14, a reflection layer 13, and a first protection layer 12 on a first substrate 21 to form a first stacking layer 2a as shown in FIG. 5.

Step 110: Select an adhesive layer 11, and utilize the adhesive layer to connect the protection layer 12 of the first stacking layer 2a to a first surface of the second substrate 10 having high thermal conductivity.

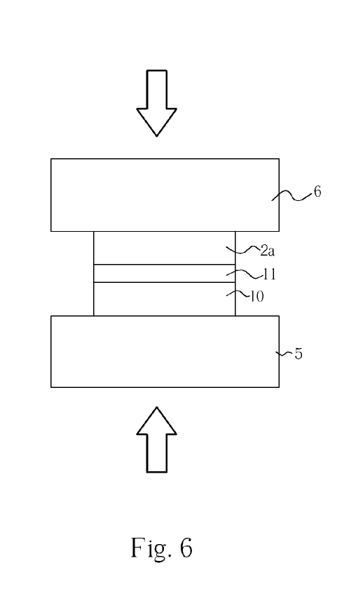

Step 120: Place a first graphite plate 5 on a second surface of the second substrate 10, and place a second graphite plate 6 on the first substrate 21 of the first stacking layer 2a as shown in FIG. 6.

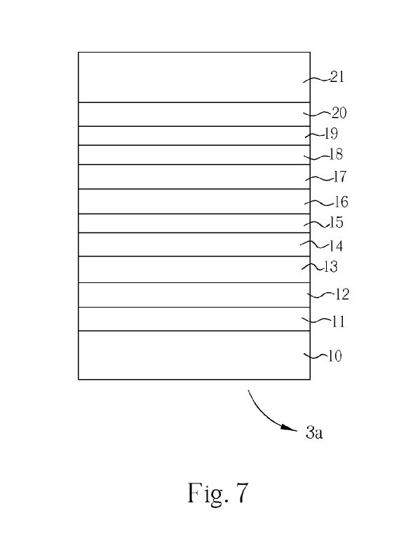

Step 130: Heat and pressure the first graphite plate 5 and the second graphite plate 6 for a specific time to form an adhesive 11 having even thickness 0.1 μm-1 μm and form a second stacking layer 3a as shown in FIG. 7.

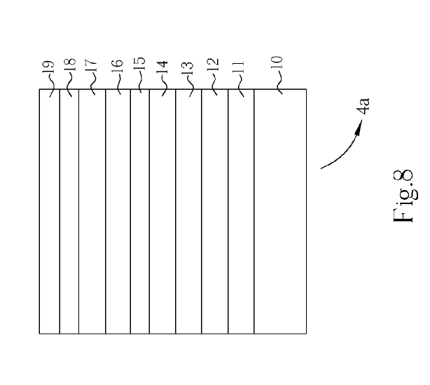

Step 140: Remove the first substrate 21 and the etching termination layer 20 to form a third stacking layer 4a as shown in FIG. 8.

Step 150: Appropriately etching the third laminated layer 4a until the first contacting layer 15 forms an exposed surface of the first contact layer 15, and respectively form the first wire electrode 9 and the second wire electrode 8 on the exposed surface of the first contact layer 15.

### Embodiment 2

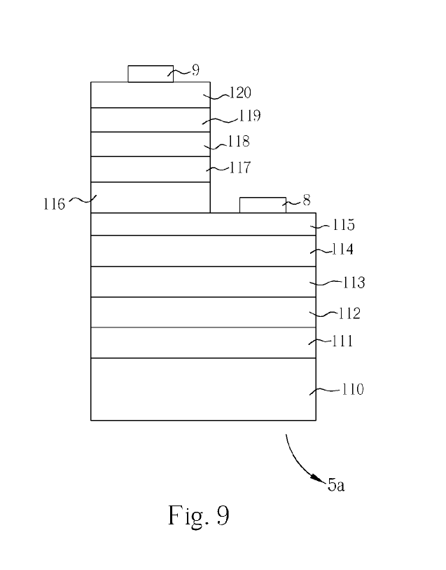

Referring to FIG. 9, the LED 5a comprises a second substrate 110 having high thermal conductivity, a reflection layer 111 formed on the second substrate 110, a first reaction layer 112 formed on the reflection layer 111, an adhesive layer 113 whose thickness is between 0.1 μm-1 μm formed on the first reaction layer 112, a second reaction layer 114 formed on the adhesive layer 113, a transparent conductive layer 115 formed on the second layer 114, wherein the upper surface of the transparent conductive layer 115 comprises a first surface area and a second surface area.

The LED 5a further comprises a first contact layer 116 formed on the first surface area, a first cladding layer 117 formed on the first contact layer 116, a light-emitting layer 118 formed on the first cladding layer 117, a second cladding layer 119 formed on the light-emitting layer 118, a second contact layer 120 formed on the second cladding layer 119, a first wire electrode 9 formed on the second contact layer 120, and a second wire electrode 8 formed on the second surface area.

Referring to FIGS. 9,10, and 11, the LED 5a is produced through the following steps:

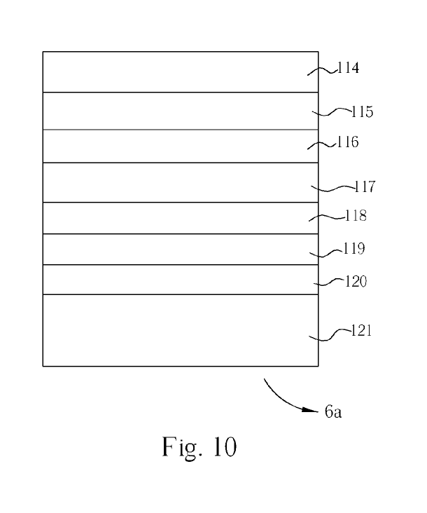

Step 200: Sequentially form a second contact layer 120, a second cladding layer 119, a light-emitting layer 118, a first cladding layer 117, a first contact layer 116, a transparent layer 115, and a second reaction layer 114 on a first substrate 121 to form a fourth stacking layer 6a as shown in FIG. 10.

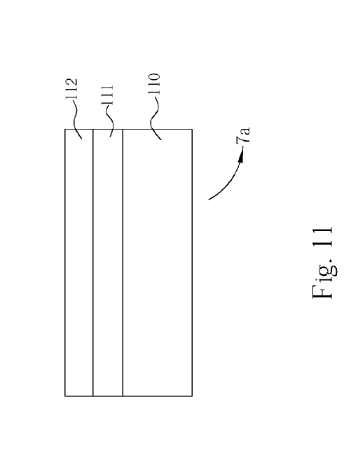

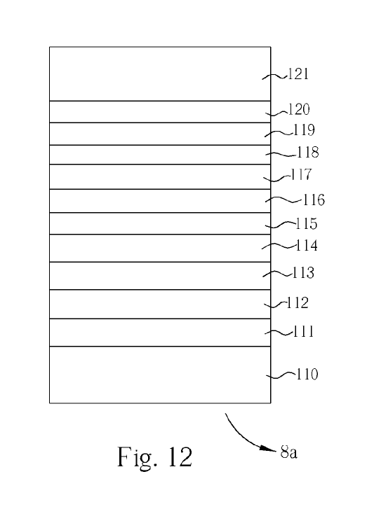

Step 210: A reflection layer 111 is formed on a second substrate 110 having high thermal conductivity, and a first reaction layer 112 is formed on the reflection layer 111 to form a fifth stacking layer 7a as shown in FIG. 11.

Step 220: An adhesive layer 113 is utilized to connect the first reaction layer 114 of the fourth stacking layer 6a to the first reaction layer 112 of the fifth layer 7a.

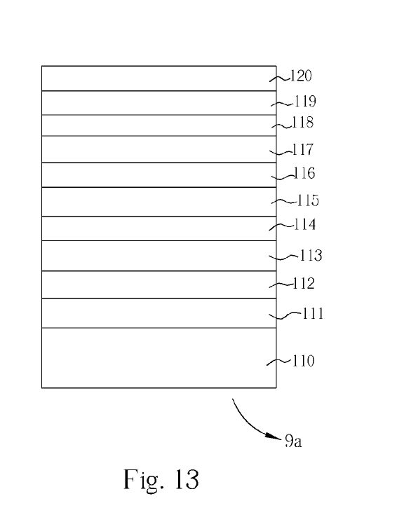

Step 230: The procedure of the adhesive connection is the same as that of the above-mentioned embodiment 1. As shown in FIG. 6, a stacking layer 6a replaces the stacking layer 2a, an adhesive layer 113 with a thickness between 0.1 μm-1 μm replace the adhesive 11, and a stacking layer 7a replace the second substrate 10. Then, a sixth stacking layer 8a is formed. Next, the first substrate 121 is removed to form a seventh stacking layer 9a, as shown in FIG. 13. Step 230: Appropriately etch the seventh stacking layer 9a and stop at the transparent conductive layer 115 to form an exposed surface area of the transparent conductive layer 115. Respectively form a first wire electrode 9 and a second wire electrode 8 on the exposed surface area of the transparent conductive layer 115.

### Embodiment 3

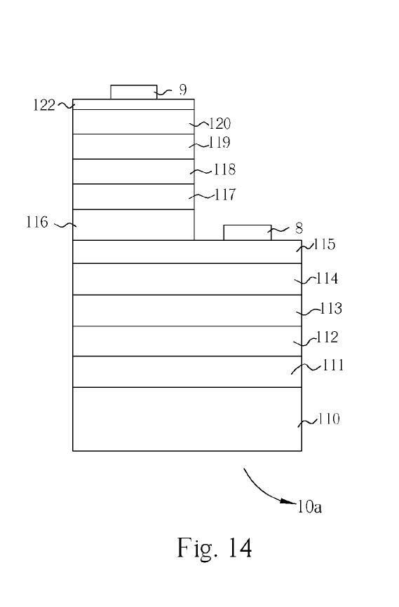

Referring to FIG. 14, which shows the other embodiment of an LED 10a having an adhesive layer according to the present invention, the structure and the production procedure are similar to the LED 5a of the embodiment 2. The difference of the present embodiment is that a transparent conductive layer 122 is formed on the second contact layer 120 in order to improve the current distribution efficiency.

The above-mentioned first substrate is made of the material selected from the group consisting of GaAs, Ge, and Sapphire.

The above-mentioned second substrate whose thermal conductivity is larger than 100 W/mk is made of the material selected from the group consisting of GaP, Si chip, SiC, Cu chip, Al chip and other replaceable materials.

The above-mentioned adhesive layer whose thickness is between 0.1 μm-1 μm is made of the material selected from the group consisting of Pl, BCB, and PFCB.

The above-mentioned first contacting layer is made of the material selected from the group consisting of GaP, GaAs, GaAsP, InGaP, AlGaInP, AlGaAs, GaN, InGaN, and AlGaN.

The above-mentioned cladding layer is made of the material selected from the group consisting of AlGaInP, AlInP, AlN, GaN, AlGaN, InGaN, and AlGaInN.

The above-mentioned light-emitting layer is made of the material selected from the group consisting of AlGaInP, InGaP, GaN, AlGaN, InGaN, and AlGaInN.

The above-mentioned second cladding layer is made of the material selected from the group consisting of AlGaInP, AlInP, AlN, GaN, AlGaN, InGaN, and AlGaInN.

The above-mentioned second contacting layer is made of the material selected from the group consisting of GaP, GaAs, GaAsP, InGaP, AlGaInP, AlGaAs, GaN, InGaN, and AlGaN.

The above-mentioned reflection layer is made of the material selected from the group consisting of In, Sn, Al, Au, Pt, Zn, Ag, Ti, Pb, Pd, Ge, Cu, AuBe, AuGe, Ni, PbSn, and AuZn.

The above-mentioned first protecting layer is made of the material selected from the group consisting of Silicon Nitride, Silicon Dioxide, Aluminum Oxide, Magnesium Oxide, Zinc Oxide, Tin Oxide, Indium Oxide, and Tin Indium Oxide.

The above-mentioned second protecting layer is made of the material selected from the group consisting of Silicon Nitride, Silicon Dioxide, Aluminum Oxide, Magnesium Oxide, Zinc Oxide, Tin Oxide, Indium Oxide, and Tin Indium Oxide.

The above-mentioned first reaction layer is made of the material selected from the group consisting of SiNx, Ti, and Cr.

The above-mentioned second reaction layer is made of the material selected from the group consisting of SiNx, Ti, and Cr.

And the above-mentioned transparent conductive layer is made of the material selected from the group consisting of Tin Indium Oxide, tin Cadmium Oxide, Tin antimony Oxide, Zinc Oxide, and Tin Zinc Oxide.

Those skilled in the art can readily understand that numerous modifications and alterations of the device and method in accordance with the invention may be made within the spirit and claims of the invention. Accordingly, the above disclosure should be construed as limited only by the metes and bounds of the appended claims.

1. A light emitting diode having an adhesive layer comprising: a high heat-dissipating substrate of thermal conductivity greater than 100 W/mk;
an LED stack; and
an adhesive layer arranged between the high heat-dissipating substrate and the LED stack, wherein a thickness of the adhesive layer is about 0.1 μm to 1 μm.

2. The light emitting diode having an adhesive layer of claim 1, wherein the high heat-dissipating substrate is made of a material selected from the group consisting of GaP, Si, SiC, Cu, and Al.

3. The light emitting diode having an adhesive layer of claim 1, wherein the adhesive layer is made of a material selected from the group consisting of Pl, BCB, and PFCB.

4. The light emitting diode having an adhesive layer of claim 1 further comprising a first protection layer, a reflection layer, and a second protection layer sequentially formed between the adhesive layer and the LED stack.

5. The light emitting diode having an adhesive layer of claim 4, wherein the first protection layer is made of a material selected from the group consisting of Silicon Nitride, Silicon Dioxide, Aluminum Oxide, Magnesium Oxide, Zinc Oxide, Tin Oxide, Indium Oxide, and Tin Indium Oxide.

6. The light emitting diode having an adhesive layer of claim 4, wherein the reflection layer is made of a material selected from the group consisting of In, Sn, Al, Au, Pt, Zn, Ag, Ti, Pb, Pd, Ge, Cu, AuBe, AuGe, Ni, PbSn, and AuZn.

7. The light emitting diode having an adhesive layer of claim 4, wherein the second protection layer is made of a material selected from the group consisting of Silicon Nitride, Silicon Dioxide, Aluminum Oxide, Magnesium Oxide, Zinc Oxide, Tin Oxide, Indium Oxide, and Tin Indium Oxide.

8. The light emitting diode having an adhesive layer of claim 1, wherein the LED stack comprises:
a first contact layer;
a first cladding layer formed on the first contact layer;
a light emitting layer formed on the first cladding layer;
a second cladding layer formed on the light emitting layer; and
a second contact layer formed on the second cladding layer.

9. The light emitting diode having an adhesive layer of claim 8, wherein the first contact layer is made of a material selected from the group consisting of GaP, GaAs, GaAsP, InGaP, AlGaInP, AlGaAs, GaN, InGaN, and AlGaN.

10. The light emitting diode having an adhesive layer of claim 8, wherein the first cladding layer is made of a material selected from the group consisting of AlGaInP, AlInP, AlN, GaN, AlGaN, InGaN, and AlGaInN.

11. The light emitting diode having an adhesive layer of claim 8, wherein the light emitting layer is made of a material selected from the group consisting of AlGaInP, InGaP, GaN, AlGaN, InGaN, and AlGaInN.

12. The light emitting diode having an adhesive layer of claim 8, wherein the second cladding layer is made of a material selected from the group consisting of AlGaInP, AlInP, AlN, GaN, AlGaN, InGaN, and AlGaInN.

13. The light emitting diode having an adhesive layer of claim 8, wherein the second contact layer is made of a material selected from the group consisting of GaP, GaAs, GaAsP, InGaP, AlGaInP, AlGaAs, GaN, InGaN, and AlGaN.

14. A light emitting diode having an adhesive layer comprising:
a high heat-dissipating substrate of thermal conductivity larger than 100 W/mk;
a reflection layer formed on the high heat-dissipating substrate;
a first reaction layer formed on the reflection layer;
an adhesive layer having a thickness of about 0.1 μm to 1 μm;
a second reaction layer formed on the adhesive layer; and
an LED stack on the second reaction layer.

15. The light emitting diode having an adhesive layer of claim 14 further comprising a transparent conductive layer formed between the second reaction layer and the LED stack.

16. The light emitting diode having an adhesive layer of claim 15, wherein the transparent conductive layer is made of a material selected from the group consisting of Tin Indium oxide, Tin cadmium Oxide, Tin Antimony Oxide, Zinc Oxide, and Tin Zinc oxide.

17. The light emitting diode having an adhesive layer of claim 14 further comprising a transparent conductive layer formed on the LED stack.

18. The light emitting diode having an adhesive layer of claim 17, wherein the transparent conductive layer is made of a material selected from the group consisting of Tin Indium oxide, Tin cadmium Oxide, Tin Antimony Oxide, Zinc Oxide, and Tin Zinc oxide.

19. The light emitting diode having an adhesive layer of claim 14, wherein the high heat-dissipating substrate of thermal conductive greater than 100 W/mk is made of a material selected from the group consisting of GaP, Si, SiC, Cu, and Al.

20. The light emitting diode having an adhesive layer of claim 14, wherein the adhesive layer is made of a material selected from the group consisting of Pl, BCB, and PFCB.

21. The light emitting diode having an adhesive layer of claim 14, wherein the reflection layer is made of a material selected from the group consisting of In, Sn, Al, Au, Pt, Zn, Ag, Ti, Pb, Pd, Ge, Cu, AuBe, AuGe, Ni, PbSn, and AuZn.

22. The light emitting diode having an adhesive layer of claim 14, wherein the first reaction layer is made of a material selected from the group consisting of SiNx, Ti, and Cr.

23. The light emitting diode having an adhesive layer of claim 14, wherein the second reaction layer is made of a material selected from the group consisting of SiNx, Ti, and Cr.

24. The light emitting diode having an adhesive layer of claim 14, wherein the LED stack comprises:
a first contact layer;
a first cladding layer formed on the first contact layer;
a light emitting layer formed on the first cladding layer;
a second cladding layer formed on the light emitting layer; and
a second contact layer formed on the second cladding layer.

25. The light emitting diode having an adhesive layer of claim 24, wherein the first contact layer is made of a material selected from the group consisting of GaP, GaAs, GaAsP, InGaP, AlGaInP, AlGaAs, GaN, InGaN, and AlGaN.

26. The light emitting diode having an adhesive layer of claim 24, wherein the first cladding layer is made of a material selected from the group consisting of AlGaInP, AlInP, AlN, GaN, AlGaN, InGaN, and AlGaInN.

27. The light emitting diode having an adhesive layer of claim 24, wherein the light emitting layer is made of a material selected from the group consisting of AlGaInP, InGaP, GaN, AlGaN, InGaN, and AlGaInN.

28. The light emitting diode having an adhesive layer of claim 24, wherein the second cladding layer is made of a material selected from the group consisting of AlGaInP, AlInP, AlN, GaN, AlGaN, InGaN, and AlGaInN.

29. The light emitting diode having an adhesive layer of claim 24, wherein the second contact layer is made of a material selected from the group consisting of GaP, GaAs, GaAsP, InGaP, AlGaInP, AlGaAs, GaN, InGaN, and AlGaN.

30. A method of manufacturing an LED having an adhesive layer comprising the following steps:
providing a first substrate;
forming an LED stack on the first substrate;
forming a second protection layer on the LED stack;
forming a reflection layer on the second protection layer;
forming a first protection layer on the reflection layer;
providing a high heat-dissipating second substrate of thermal conductivity larger than or equal to 100 W/mk; and
utilizing an adhesive layer having a thickness of about 0.1 μm to 1 μm to adhere the second heat heat-dissipating substrate and the first protection layer.

31. The method of manufacturing an LED having an adhesive layer of claim 30, wherein the formulation of the adhesive layer having a thickness of about 0.1 μm to 1 μm comprises the steps of:
providing a first graphite plate;
arranging an adhesive layer on the first graphite plate to adhere the first high heat-dissipating substrate and the first reaction layer to form a stack or arranging an adhesive layer to adhere the first reaction layer and the second reaction layer to form a stack;
providing a second graphite plate on the stack; and
performing a heating and pressuring process on the top of the second graphite plate and the bottom of the first graphite plate.

32. The method of manufacturing an LED having an adhesive layer of claim 30, wherein the first substrate is made of a material selected from the group consisting of GaAs, Ge, and Sapphire.

33. The method of manufacturing an LED having an adhesive layer of claim 30, wherein the second high heat-dissipating substrate is made of a material selected from the group consisting of GaP, Si, SiC, Cu, and Al.

34. The method of manufacturing an LED having an adhesive layer of claim 30, wherein the reflection layer is made of a material selected from the group consisting of In, Sn, Al, Au, Pt, Zn, Ag, Ti, Pb, Pd, Ge, Cu, AuBe, AuGe, Ni, PbSn, and AuZn.

35. The method of manufacturing an LED having an adhesive layer of claim 30, wherein the adhesive layer is made of a material selected from the group consisting of Pl, BCB, and PFCB.

36. The method of manufacturing an LED having an adhesive layer of claim 30, wherein the first protecting layer is made of a material selected from the group consisting of Silicon Nitride, Silicon Dioxide, Aluminum Oxide, Magnesium Oxide, Zinc Oxide, Tin Oxide, Indium Oxide, and Tin Indium Oxide.

37. The method of manufacturing an LED having an adhesive layer of claim 30, wherein the second protecting layer is made of a material selected from the group consisting of Silicon Nitride, Silicon Dioxide, Aluminum Oxide, Magnesium Oxide, Zinc Oxide, Tin Oxide, Indium Oxide, and Tin Indium Oxide.

38. The method of manufacturing an LED having an adhesive layer of claim 30, wherein the first reaction layer is made of a material selected from the group consisting of SiNx, Ti, and Cr.

39. The method of manufacturing an LED having an adhesive layer of claim 30, wherein the second reaction layer is made of a material selected from the group consisting of SiNx, Ti, and Cr.

40. A method of manufacturing an LED having an adhesive layer comprising:
providing a first substrate;
forming an LED stack on the first substrate;
forming a second reaction layer on the LED stack;
providing a second high heat-dissipating substrate providing with a thermal conductivity larger than or equal to 100 W/mk;
forming a reflection layer on the second high heat-dissipating substrate;
forming a first reaction layer on the reflection layer; and
utilizing an adhesive layer having a thickness of about 0.1 μm to 1 μm to adhere the first reaction layer and the second reaction layer.

41. The method of manufacturing an LED having an adhesive layer or claim 40, wherein the formulation of the adhesive layer having a thickness of about 0.1 μm to 1 μm comprises the steps of:
providing a first graphite plate;
arranging an adhesive layer on the first graphite plate to adhere the first high heat-dissipating substrate and the first reaction layer to form a stack or arranging an adhesive layer to adhere the first reaction layer and the second reaction layer to form a stack;
providing a second graphite plate on the stack; and
performing a heating and pressuring process on the top of the second graphite plate and the bottom of the first graphite plate.

42. The method of manufacturing an LED having an adhesive layer of claim 40, wherein the first substrate is made of the material selected from the group consisting of GaAs, Ge, and Sapphire.

43. The method of manufacturing an LED having an adhesive layer of claim 40, wherein the second high heat-dissipating substrate is made of the material selected from the group consisting of GaP, Si, SiC, Cu, and Al.

44. The method of manufacturing an LED having an adhesive layer of claim 40, wherein the reflection layer is made of the material selected from the group consisting of In, Sn, Al, Au, Pt, Zn, Ag, Ti, Pb, Pd, Ge, Cu, AuBe, AuGe, Ni, PbSn, and AuZn.

45. The method of manufacturing an LED having an adhesive layer or claim 40, wherein the adhesive layer is made of the material selected from the group consisting of Pl, BCB, and PFCB.

46. The method of manufacturing an LED having an adhesive layer of claim 40 further comprising:
forming a transparent conductive layer between the second reaction layer and the LED stack.

47. The method of manufacturing an LED having an adhesive layer of claim 46, wherein the transparent conductive layer is made of a material selected from the group consisting of Tin Indium Oxide, Tin Cadmium Oxide, Tin Antimony Oxide, Zinc Oxide, and Tin Zinc Oxide.
